(19) United States
(12) Patent Application Publication
(10) Pub. No.: US 2025/0337432 A1
(43) Pub. Date: Oct. 30, 2025

(54) APPARATUS AND METHOD FOR DATA CONVERSION

(71) Applicant: SAMSUNG ELECTRONICS CO., LTD., SUWON-SI (KR)

(72) Inventors: MOOYEOL CHOI, Suwon-si (KR); MYUNG-JIN LEE, Suwon-si (KR)

(21) Appl. No.: 19/045,602

(22) Filed: Feb. 5, 2025

(30) Foreign Application Priority Data
Apr. 25, 2024 (KR) 10-2024-0055421

(51) Int. Cl. H03M 1/46

(52) U.S. Cl. CPC H03M 1/46

(57) ABSTRACT

An analog-to-digital converter (ADC) including: a digital-to-analog converter (DAC) including a plurality of current cells; and an amplifier including a bias terminal configured to receive a current supplied from the plurality of current cells, wherein each of the plurality of current cells includes: a power source; a first switch configured to couple the power source to input terminals of the amplifier; and a second switch configured to couple the power source to the bias terminal.

### CROSS-REFERENCE TO RELATED APPLICATION

This application claims priority under 35 U.S.C. § 119 to Korean Patent Application No. 10-2024-0055421, filed on Apr. 25, 2024, in the Korean Intellectual Property Office, the disclosure of which is incorporated by reference herein in its entirety.

### 1. TECHNICAL FIELD

The present disclosure relates to an apparatus and method for data conversion.

### 2. DESCRIPTION OF THE RELATED ART

A data converter is a device that converts input signals between analog and digital formats.

An analog-to-digital converter (ADC), a type of data converter, converts analog signals into digital signals, and a digital-to-analog converter (DAC), another type of data converter, converts digital signals into analog signals.

Some data converters may include an internal DAC to facilitate format conversion.

### SUMMARY

According to an embodiment of the present disclosure, there is provided an analog-to-digital converter (ADC) including: a digital-to-analog converter (DAC) including a plurality of current cells; and an amplifier including a bias terminal configured to receive a current supplied from the plurality of current cells, wherein each of the plurality of current cells includes: a power source; a first switch configured to couple the power source to input terminals of the amplifier; and a second switch configured to couple the power source to the bias terminal.

According to an embodiment of the present disclosure, there is provided a DAC including: a plurality of current cells; and an amplifier including a bias terminal configured to receive a current supplied from the plurality of current cells, wherein each of the plurality of current cells includes: a power source; a first switch configured to couple the power source to input terminals of the amplifier; and a second switch configured to couple the power source to the bias terminal.

According to an embodiment of the present disclosure, there is provided a method of converting input data using an ADC, the method including: changing a state of a switch configured to couple a power source, included in a current cell of a DAC included in the ADC, to a bias terminal of an amplifier included in the ADC, based on an input digital value of the DAC; and biasing the amplifier using a current supplied from the power source to the amplifier through the switch.

### BRIEF DESCRIPTION OF THE DRAWINGS

The above and/or other features of the present disclosure will become clearer and more easily understood from the following description of embodiments, taken in conjunction with the accompanying drawings in which:

FIG. 1 is a circuit diagram illustrating an analog-to-digital converter (ADC) according to an embodiment;

FIG. 2 is a block diagram illustrating a digital-to-analog converter (DAC) according to an embodiment;

FIGS. 3 and 4 are circuit diagrams illustrating an ADC according to an embodiment;

FIG. 5 is a diagram illustrating a flow of current in an ADC including a tri-level current steering DAC according to an embodiment;

FIG. 6 is a block diagram illustrating an ADC according to an embodiment;

FIG. 7 is a diagram illustrating an ADC according to an embodiment;

FIG. 8 is a diagram illustrating an example of an amplifier of an ADC according to an embodiment;

FIG. 9 is a diagram illustrating another example of an amplifier of an ADC according to an embodiment; and

FIG. 10 is a flowchart illustrating a method of converting input data according to an embodiment.

### DETAILED DESCRIPTION OF THE EMBODIMENTS

Hereinafter, embodiments of the present disclosure will be described in detail with reference to the accompanying drawings. In the descriptions, identical reference numerals indicate corresponding components, and redundant explanations will be omitted for clarity.

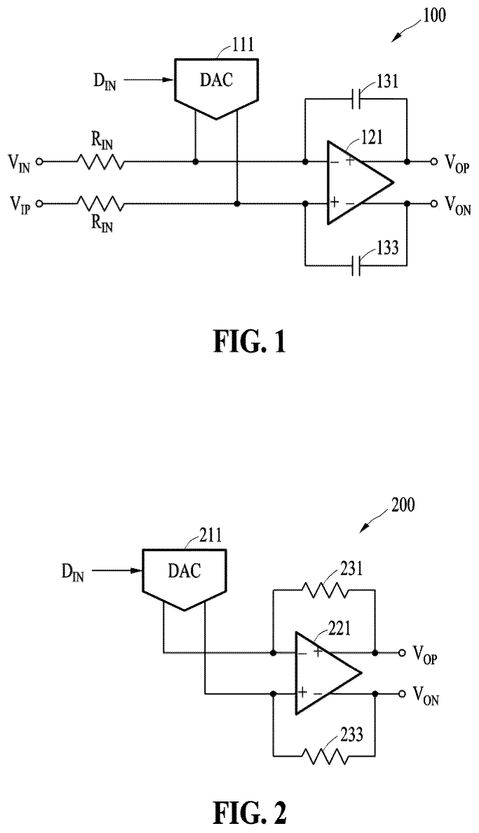

FIG. 1 is a circuit diagram illustrating an analog-to-digital converter (ADC) according to an embodiment. FIG. 1 illustrates an integrator for the ADC.

Referring to FIG. 1, according to an embodiment, an ADC 100 (e.g., a delta-sigma ADC) may include a digital-to-analog converter (DAC) 111 (or an internal DAC), an amplifier 121 (e.g., an operational-amplifier), and feedback circuits 131 and 133.

FIG. 1 illustrates the DAC 111 and the amplifier 121 in the ADC 100. The ADC 100 may also include additional components in addition to those illustrated in FIG. 1. The circuit configuration of the ADC 100 illustrated in FIG. 1 may be changed based on these additional components. Thus, it is clear to those of ordinary skill in the art that the scope of the present disclosure is not limited to the specific circuit configuration illustrated in FIG. 1. The drawings that will be described below should not be interpreted as limiting in any way.

Although the present disclosure is described using a differential input as an example, this is solely for illustrative purposes. The technical details of the present disclosure may apply to other types of inputs (e.g., single-ended inputs) in addition to differential inputs.

The ADC 100 may generate output digital values (e.g., quantized values of output voltages V_{Op} and V_{ON}) based on a difference between a first input analog signal V_{IN} and a second input analog signal V_{IP}. A pair of resistors R_{IN} may be disposed between input terminals for receiving the first input analog signal V_{IN} and the second input analog signal V_{IP}. and the DAC 111.

During a comparison process, the DAC 111 may convert an input digital value generated by a component (e.g., a controller) of the ADC 100 into an analog signal (e.g., an analog voltage). The ADC 100 may use an analog signal output from the DAC 111 to estimate an output digital value corresponding to the difference between the first input analog signal V_{IN} and the second input analog signal V_{IP}.

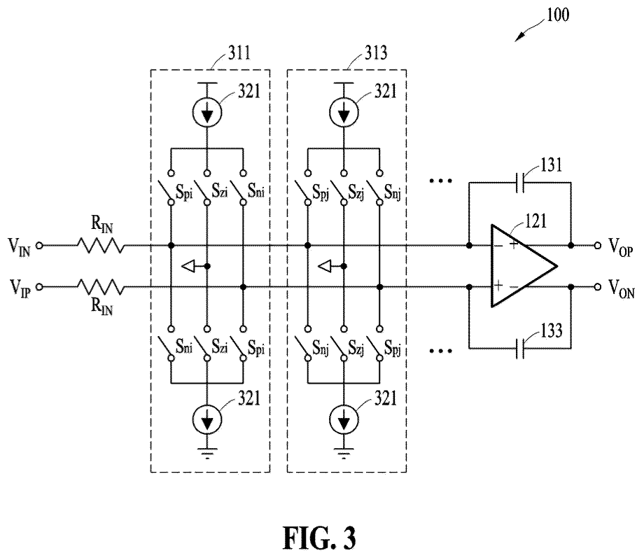

The DAC 111 may include a tri-level current steering DAC. The circuit configuration of the ADC 100, based on a tri-level current steering device, will be described in detail with reference to FIGS. 3 to 5.

The amplifier 121, along with the feedback circuits 131 and 133, may operate as an integrator. The amplifier 121 may generate a digital signal corresponding to the difference between the first input analog signal V_{IN} and the second input analog signal V_{IP}, based on an output of the DAC 111.

Each of the feedback circuits 131 and 133 may include a feedback capacitor. Each of the feedback circuits 131 and 133 may further include a feedback resistor.

FIG. 2 is a block diagram illustrating a DAC according to an embodiment.

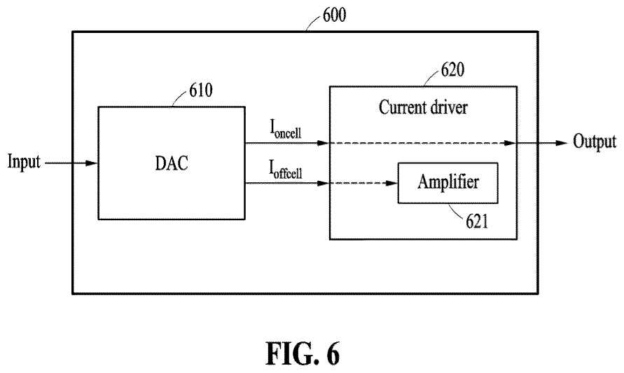

Referring to FIG. 2, according to an embodiment, a DAC 200 may include a DAC 211 (or an internal DAC) (e.g., the DAC 111 of FIG. 1 or a DAC 610 of FIG. 6), an amplifier 221 (e.g., the amplifier 121 of FIG. 1), and feedback circuits 231 and 233.

The DAC 211 may convert an input digital value (e.g., a digital code such as “100101”) into an analog signal. The amplifier 221 may amplify an output of the DAC 211.

The technical concepts related to the ADC described in the present disclosure may also be applicable to the DAC 211.

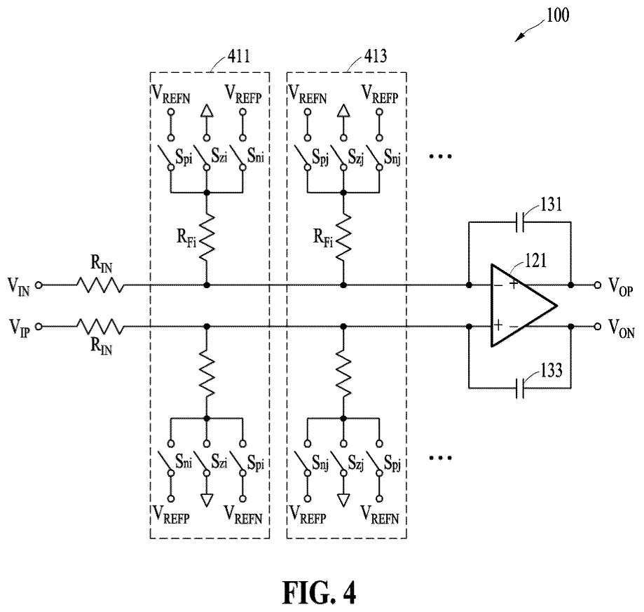

FIGS. 3 and 4 are circuit diagrams illustrating an ADC according to an embodiment.

FIG. 3 illustrates an integrator for an ADC based on a current source, and FIG. 4 is a block diagram illustrating an integrator for an ADC based on a voltage source. The current source is denoted by reference numeral 321 in FIG. 3, and the voltage source is denoted by reference indicators V_{RFEN} and V_{REFP} in FIG. 4.

Referring to FIGS. 3 and 4, according to an embodiment, a DAC (e.g., the DAC 111 of FIG. 1) in an ADC 100 may include a tri-level current steering DAC. While the present disclosure is described using the tri-level current steering DAC as an example, it is not limited thereto. For example, the technical concepts of the present disclosure may also be applicable to a binary current steering DAC.

The DAC 111 may include a plurality of current cells. For example, the DAC 111 may include current cells 311 and 313 that are based on a current source, or current cells 411 and 413 that are based on a voltage source. Hereinafter, for convenience of description, the present disclosure will be described using current cells based on a current source as an example.

The number of current cells included in the ADC 100 may be determined based on specifications (e.g., a resolution) of the ADC 100. In the present disclosure, the ADC is described using two current cells as an example; however, the scope of the disclosure is not limited thereto.

The current cells 311 and 313 may correspond to respective bits of an input digital value of the DAC 111. For example, when the input digital value of the DAC 111 is “10” and when the DAC 111 includes the above two current cells 311 and 313, the current cell 311 may correspond to a bit value “1” and the current cell 313 may correspond to a bit value “0.”

Each of the current cells 311 and 313 may include switches Sₚ and Sₙ to couple a current source 321 to input terminals (e.g., a positive input terminal and/or a negative input terminal) of an amplifier 121. Each of the plurality of current cells 311 and 313 may include a switch S_{z} to couple the current source 321 to ground. In FIGS. 3 and 4, “i” and “j” represent indices of the current cells 311 and 313, respectively. States of the switches Sₚ, S_{z}, and Sₙ may be determined based on a bit value corresponding to a current cell. For example, the first switch Sₚ may be closed when a value of a corresponding bit is “1,” the second switch S_{z} may be closed when a value of a corresponding bit is “0,” and the third switch Sₙ may be closed when a value of a corresponding bit is “−1.” For example, when the input digital value of the DAC 111 is “10” and when the DAC 111 includes the above two current cells 311 and 313, a first switch Sₚᵢ of the current cell 311 and a second switch S_{zj} of the current cell 313 may be switched on. In other words, the first switch Sₚᵢ of the current cell 311 and the second switch S_{zj} of the current cell 313 may be closed.

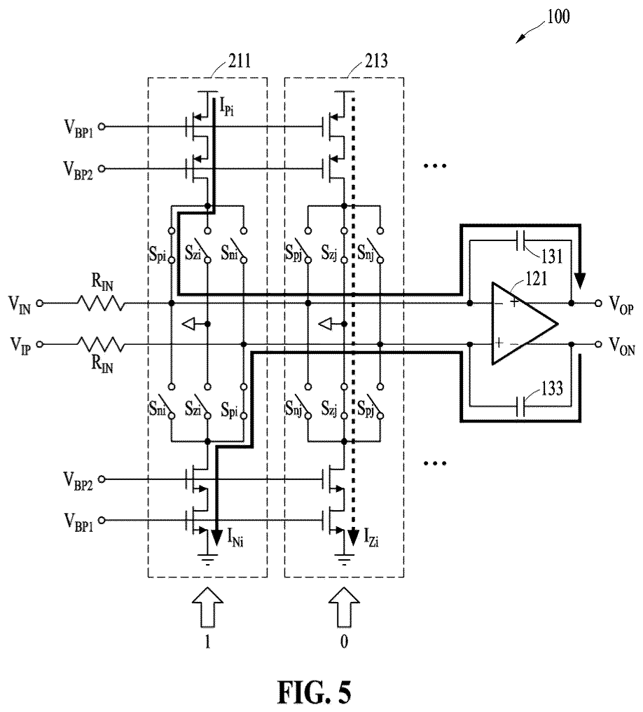

FIG. 5 is a diagram illustrating a flow of current in an ADC including a tri-level current steering DAC according to an embodiment.

Referring to FIG. 5, according to an embodiment, an ADC 100 may need to turn off a current cell (e.g., the current cell 213) corresponding to a bit value of “0” to enhance the dynamic range. However, the ADC 100 may allow a current I_{zi} supplied from the power source (e.g., a current source) of the current cell (e.g., the current cell 213) to flow to the ground to improve total harmonic distortion (THD). As a result of the current I_{zi} flowing to the ground, the power consumption of the ADC 100 may increase. Thus, a method of reusing the current I_{zi} may be necessary. For example, using the current I_{zi} as a bias current of the amplifier 121 could be considered.

Thermal noise generated by the amplifier 121 in the ADC 100 may degrade the dynamic range of the ADC 100. The thermal noise of the amplifier 121 can be reduced by increasing the input transconductance of the amplifier 121. To achieve this, one approach could be to increase the bias current of the amplifier 121. However, increasing the bias current leads to higher power consumption in the ADC 100.

If the current I_{zi} from the current cell (e.g., the current cell 213) corresponding to the bit value of “0” among a plurality of current cells 211 and 213 in the ADC 100 is utilized as the bias current for the amplifier 121, the dynamic range of the ADC 100 may be enhanced and the power consumption of the ADC 100 may be reduced.

In FIG. 5, current cells 211 and 213 may further include transistors with gates for receiving voltages V_{BP1} and V_{BP2}. Furthermore, a current I_{Pi} may flow from the current cell 211 to the output terminal of the amplifier 121. In addition, a current I_{Ni} may be fed back from the output terminal of the amplifier 121 to the current cell 211.

FIG. 6 is a block diagram illustrating an ADC according to an embodiment.

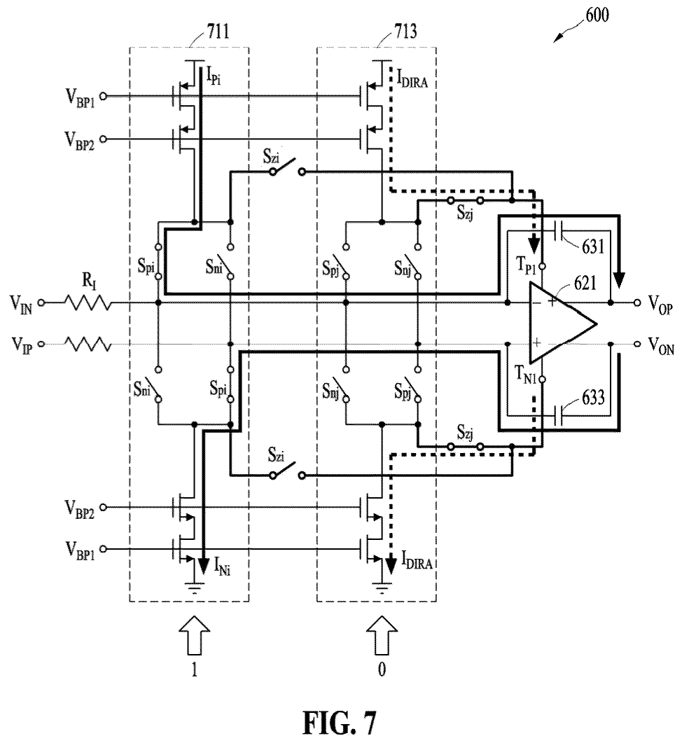

Referring to FIG. 6, according to an embodiment, an ADC 600 may include a DAC 610, and a current driver 620 (or a voltage driver) (e.g., an integrator). The current driver 620 may include an amplifier 621, and feedback circuits (e.g., feedback circuits 631 and 633 of FIG. 7).

The DAC 610 may include a current steering DAC (e.g., a tri-level current steering DAC). The DAC 610 may be configured to supply, to the amplifier 621, a current I_{offcell} supplied from current cells (e.g., current cells corresponding to a bit value “0”) that are currently inactive, among a plurality of current cells of the DAC 610. The current I_{offcell} may be used as a bias current of the amplifier 621. The expression “offcell,” as used herein, refers to a cell (e.g., a current cell 713 of FIG. 7) that is currently inactive.

The current driver 620 may generate an output (e.g., an output voltage or an output current) based on a current I_{oncell} supplied from current cells (e.g., current cells corresponding to a bit value of “1” or “−1”) that are currently active, among the plurality of current cells of the DAC 610. The expression “oncell,” as used herein, refers to a cell (e.g., a current cell 711 of FIG. 7) that is currently active.

FIG. 7 is a diagram illustrating an ADC according to an embodiment.

Referring to FIG. 7, according to an embodiment, an ADC 600 may include a DAC (e.g., the DAC 610 of FIG. 6), the feedback circuits 631 and 633, and an amplifier 621.

The feedback circuits 631 and 633 may substantially be the same as the feedback circuits 131, 133, 231, and 233 described with reference to FIGS. 1 and 2 to 5. Redundant descriptions are omitted herein.

The amplifier 621 may include bias terminals T_{P1} and T_{N1} to receive a bias current from at least one of the plurality of current cells 711 and 713. The amplifier 621 may be similar to the amplifier 121 and 221 described with reference to FIGS. 1 and 2 to 5. Redundant descriptions are omitted herein.

The DAC 610 may include the plurality of current cells 711 and 713. Each of the plurality of current cells 711 and 713 may include a power source (e.g., a current source or a voltage source), switches Sₚ and Sₙ to couple the power source to input terminals of the amplifier 621, and a switch S_{z} to couple the power source to the bias terminals T_{P1} and T_{N1} of the amplifier 621. In FIG. 7, “i” and “j” represent an index of the current cell 711 and an index of the current cell 713, respectively. States of the switches Sₚ, S_{z}, and Sₙ may be determined based on a bit value corresponding to a current cell. For example, the first switch Sₚ may be closed when a value of a corresponding bit is “1,” the second switch S_{z} may be closed when a value of a corresponding bit is “0,” and the third switch Sₙ may be closed when a value of a corresponding bit is “−1.” For example, when the input digital value of the DAC 610 is “10” and when the DAC 610 includes the above two current cells 711 and 713, a first switch Sₚᵢ of the current cell 711 and a second switch S_{zj} of the current cell 713 may be switched on.

In the inactive state of the plurality of current cells 711 and 713, the plurality of current cells 711 and 713 may supply a current received from the power source to the amplifier 621 through the second switch S_{z}. The amplifier 621 may use a current I_{DIRA} (e.g., the current I_{offcell} of FIG. 6) supplied from one or more inactive current cells (e.g., the current cell 713) as a bias current.

In FIG. 7, a switch Szᵢ is provided between a node connected to a terminal of switch Sₙᵢ and the amplifier 621, and another switch Szᵢ is provided between a node connected to a terminal of switch Sₚᵢ and the amplifier 621.

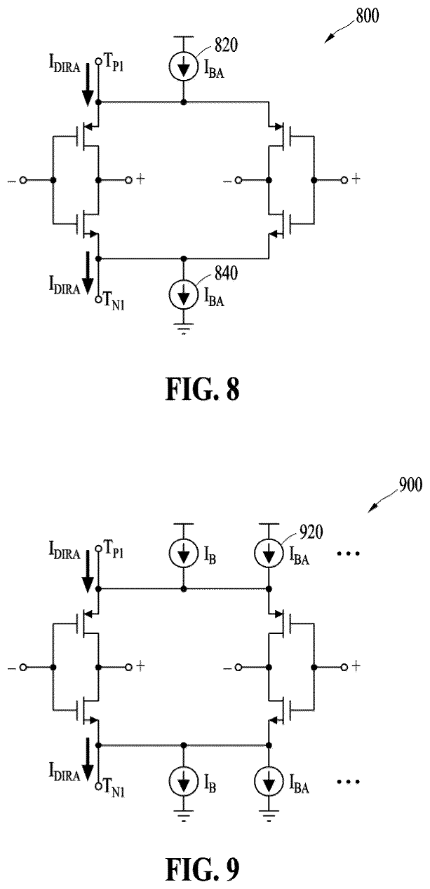

FIG. 8 is a diagram illustrating an example of an amplifier of an ADC according to an embodiment.

Referring to FIG. 8, according to an embodiment, an amplifier 800 (e.g., the amplifier 621 of FIGS. 6 and 7) of an ADC (e.g., the ADC 600 of FIGS. 6 and 7) may include a power source 820 (e.g., a current source or a voltage source). As described above, the present disclosure is described based on a differential input, and thus, the amplifier 800 may further include a power source 840 corresponding to the power source 820.

The amplifier 800 may be biased using both a bias current I_{BA} provided by the power sources 820 and 840 and a current I_{DIRA} supplied from inactive current cells (e.g., the inactive current cell 713 of FIG. 7).

The amplifier 800 may include a plurality of transistors along pathways between the power sources 820 and 840.

The power sources 820 and 840 may adaptively (or variably) provide the bias current I_{BA} to the amplifier 800, based on the current I_{DIRA} supplied from the inactive current cells. The magnitude of the current I_{DIRA} may increase as the number of inactive current cells increases. The number of inactive current cells may be determined by an input digital value (e.g., the magnitude of the input digital value) of a DAC (e.g., the DAC 610 of FIG. 6) included in the ADC 600 or a DAC (e.g., the DAC 200 of FIG. 2). For example, as the input digital value decreases, the number of inactive current cells may increase.

Since the power sources 820 and 840 variably provide the bias current I_{BA} to the amplifier 800 based on the current I_{DIRA} Supplied from the inactive current cells, a reduction in dynamic range performance of the amplifier 800 may be prevented.

To variably provide a bias current to the amplifier 800, the drive voltages of the power sources 820 and 840 may be adjusted based on the input digital value of the DAC 610.

FIG. 9 is a diagram illustrating another example of an amplifier of an ADC according to an embodiment.

According to an embodiment, an amplifier 900 (e.g., the amplifier 621 of FIGS. 6 and 7) of an ADC (e.g., the ADC 600 of FIGS. 6 and 7) of FIG. 9 may be similar to the ADC 800 described with reference to FIG. 8. Redundant descriptions are omitted herein.

The amplifier 900 may further include a plurality of power sources 920 that are separately switched on or off based on a current I_{DIRA} supplied from an inactive current cell (e.g., the inactive current cell 713 of FIG. 7). For example, as the magnitude of the current I_{DIRA} decreases, the number of power sources switched on may increase, thereby preventing a reduction in the THD performance of the amplifier 800.

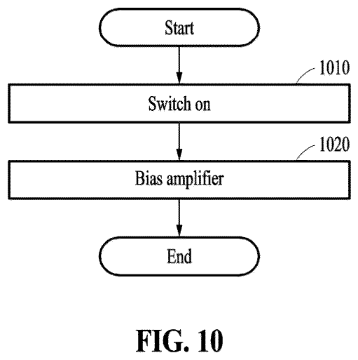

FIG. 10 is a flowchart illustrating a method of converting input data according to an embodiment.

Referring to FIG. 10, operations 1010 and 1020 may be performed sequentially, but are not limited thereto. For example, operations 1010 and 1020 may be performed in parallel. Operations 1010 and 1020 may be substantially the same as the operations of the ADC 600 described with reference to FIGS. 6 and 7. Redundant descriptions are omitted herein.

In operation 1010, the ADC 600 (or a controller outside the ADC 600) may change a state of a switch (e.g., the switch S_{z} of FIG. 7) to couple a power source included in a current cell (e.g., the current cell 713 of FIG. 7) of the DAC 610 to a bias terminal (e.g., the bias terminal T_{P1} or T_{N1} of FIGS. 7 and 8) of an amplifier (e.g., the amplifier 621 of FIGS. 6 and 7, the amplifier 800 of FIG. 8, and/or the amplifier 900 of FIG. 9) included in the ADC 600, based on an input digital value of a DAC (e.g., the DAC 610 of FIG. 6) included in the ADC 600.

In operation 1020, the ADC 600 (or a controller outside the ADC 600) may bias the amplifier 621, 800, 900 using a current (e.g., the current I_{DIRA} of FIGS. 7 to 9) supplied from a power source included in the current cell 713 to the amplifier 621, 800, 900, through the switch S_{z}.

According to an embodiment, the ADC 600 may include the DAC 610 including the plurality of current cells 711 and 713. The ADC 600 may include the amplifier 621, 800, 900 including the bias terminal T_{P1}, T_{N1} to receive a current supplied from the plurality of current cells 711 and 713.

Each of the plurality of current cells 711 and 713 may include a power source. Each of the plurality of current cells 711 and 713 may include a first switch Sₚ to couple the power source to input terminals of the amplifier 621, 800, 900. Each of the plurality of current cells 711 and 713 may include a second switch S_{z} to couple the power source to the bias terminal T_{P1}, T_{N1}.

The amplifier 621, 800, 900 may be biased using a current I_{DIRA} supplied through the second switch S_{z}.

The ADC 600 may further include a third switch Sₙ to couple the power source to the input terminals of the amplifier 621, 800, 900.

The ADC 600 may further include at least one bias source to provide a bias current to the amplifier 621, 800, 900 based on an input digital value of the DAC 610.

The at least one bias source may include a plurality of bias sources 920 that are separately switched on or off based on the input digital value, to bias the amplifier with the current supplied from the plurality of current cells 711 and 713.

The DAC 610 may include a current steering DAC.

The first switch Sₚ may be switched on in response to a first bit value (e.g., “1”). The second switch S_{z} may be switched on in response to a second bit value (e.g., “0”).

The third switch S₁ may be switched on in response to a third bit value (e.g., “−1”).

The ADC 600 may further include the first feedback circuit 631 to couple a first input terminal of the amplifier 621, 800, 900 to a first output terminal of the amplifier 621, 800, 900.

The ADC 600 may further include the second feedback circuit 633 to couple a second input terminal of the amplifier 621, 800, 900 to a second output terminal of the amplifier 621, 800, 900.

According to an embodiment, a method of converting input data using an ADC may include adjusting a state of a switch that couples a power source, included in a current cell of a DAC within the ADC, to a bias terminal of an amplifier also included in the ADC, based on an input digital value of the DAC. The method may further include biasing the amplifier by utilizing the current supplied from the power source included in the current cell, which is routed to the amplifier through the switch.

The ADC may further include one or more switches to couple the power source to input terminals of the amplifier.

The biasing of the amplifier may include using the current supplied from the power source in the current cell, routed to the amplifier through the switch, in combination with a current supplied from at least one bias source configured to provide a bias current to the amplifier.

The at least one bias source may include a plurality of bias sources that are separately switched on or off based on the input digital value.

The ADC may include a current steering DAC.

The adjusting of the state of the switch may include closing the switch when the current cell is currently inactive.

The ADC may further include a first feedback circuit configured to couple a first input terminal of the amplifier to a first output terminal of the amplifier.

The ADC may further include a second feedback circuit configured to couple a second input terminal of the amplifier to a second output terminal of the amplifier.

It should be appreciated that various embodiments of the disclosure and the terms used herein are not intended to limit the technological features to any particular embodiment, but rather encompass various changes, equivalents, or replacements for corresponding embodiments. It is to be understood that a singular form of a noun may refer to one or more items, unless the context clearly indicates otherwise. As used herein, “A or B,” “at least one of A and B,” “at least one of A or B,” “A, B or C,” “at least one of A, B and C,” and “at least one of A, B, or C,” may refer to any one or more of the listed items, or any combination thereof. Terms such as “1st” and “2nd,” or “first” and “second” may be used to simply distinguish a corresponding component from other components, and do not imply any limitation regarding importance or order. Furthermore, when a component (e.g., a first component) is described as “coupled with,” “coupled to,” “connected with,” or “connected to” another component (e.g., a second component), with or without the terms “operatively” or “communicatively,” the component may be coupled with the other component directly (e.g., by a wire), wirelessly, or via a third component.

A method according to various embodiments of the disclosure may be included and provided as part of a computer program product. The computer program product may be sold as a product between a seller and a buyer. The computer program product may be distributed in the form of a machine-readable storage medium (e.g., compact disc read-only memory (CD-ROM)), or made available for download or upload online via an application store (e.g., PlayStore™), or directly between two user devices (e.g., smartphones). If distributed online, at least part or all of the computer program product may be temporarily generated or stored in a machine-readable storage medium, such as memory of the manufacturer's server, a server of the application store, or a relay server.

According to various embodiments, each component (e.g., a module or a program) described above may include a single entity or multiple entities, with some entities potentially disposed in different components. According to various embodiments, one or more of the above-described components or operations may be omitted, or other components or operations may be added. Alternatively, a plurality of components (e.g., modules or programs) may be integrated into a single component. In such cases, the integrated component may still perform the functions of each of the original components in the same or a similar manner as before integration. According to various embodiments, operations performed by the module, the program, or another component may be carried out sequentially, in parallel, repeatedly, or heuristically, or in a different order. Some operations may be omitted or added.

The effects to be achieved are not limited to those described above, and additional effects not mentioned above will be readily understood by those of ordinary skill in the art upon review of this document.

What is claimed is:

1. An analog-to-digital converter (ADC) comprising:
a digital-to-analog converter (DAC) comprising a plurality of current cells; and
an amplifier comprising a bias terminal configured to receive a current supplied from the plurality of current cells,
wherein each of the plurality of current cells comprises:
a power source;
a first switch configured to couple the power source to input terminals of the amplifier; and
a second switch configured to couple the power source to the bias terminal.

2. The ADC of claim 1, wherein the amplifier is biased using a current supplied through the second switch.

3. The ADC of claim 1, further comprising:
a third switch configured to couple the power source to the input terminals of the amplifier.

4. The ADC of claim 2, further comprising:
at least one bias source configured to provide a bias current to the amplifier based on an input digital value of the DAC.

5. The ADC of claim 4, wherein the at least one bias source comprises a plurality of bias sources that are separately switched on or off in response to the input digital value, the plurality of bias source being configured to bias the amplifier with a current supplied from the plurality of current cells.

6. The ADC of claim 1, wherein the DAC comprises a current steering DAC.

7. The ADC of claim 1, wherein
the first switch is switched on in response to a first bit value, and
the second switch is switched on in response to a second bit value.

8. The ADC of claim 3, wherein the third switch is switched on in response to a third bit value.

9. The ADC of claim 1, further comprising:
a first feedback circuit configured to couple a first input terminal of the amplifier to a first output terminal of the amplifier.

10. The ADC of claim 9, further comprising:
a second feedback circuit configured to couple a second input terminal of the amplifier to a second output terminal of the amplifier.

11. A digital-to-analog converter (DAC) comprising:
a plurality of current cells; and
an amplifier comprising a bias terminal configured to receive a current supplied from the plurality of current cells,
wherein each of the plurality of current cells comprises:
a power source;
a first switch configured to couple the power source to input terminals of the amplifier; and
a second switch configured to couple the power source to the bias terminal.

12. A method of converting input data using an analog-to-digital converter (ADC), the method comprising:
changing a state of a switch configured to couple a power source, included in a current cell of a digital-to-analog converter (DAC) included in the ADC, to a bias terminal of an amplifier included in the ADC, based on an input digital value of the DAC; and
biasing the amplifier using a current supplied from the power source to the amplifier through the switch.

13. The method of claim 12, wherein the ADC further comprises one or more switches configured to couple the power source to input terminals of the amplifier.

14. The method of claim 12, wherein the biasing of the amplifier comprises biasing the amplifier using the current supplied from the power source to the amplifier through the switch, and a current supplied from at least one bias source configured to provide a bias current to the amplifier.

15. The method of claim 14, wherein the at least one bias source comprises a plurality of bias sources that are separately switched on or off based on the input digital value.

16. The method of claim 12, wherein the DAC comprises a current steering DAC.

17. The method of claim 12, wherein the changing of the state of the switch comprises closing the switch when the current cell is inactive.

18. The method of claim 12, wherein the ADC further comprises a first feedback circuit configured to couple a first input terminal of the amplifier to a first output terminal of the amplifier.

19. The method of claim 18, wherein the ADC further comprises a second feedback circuit configured to couple a second input terminal of the amplifier to a second output terminal of the amplifier.
